(19) United States
(12) Patent Application Publication
(10) Pub. No.: US 2026/0171159 A1
(43) Pub. Date: Jun. 18, 2026

(54) MEMORY DEVICE AND METHOD FOR OPERATING THEREOF

(71) Applicant: SK hynix Inc., Gyeonggi-do (KR)

(72) Inventor: Young Hwan CHOI, Gyeonggi-do (KR)

(21) Appl. No.: 19/269,049

(22) Filed: Jul. 15, 2025

(30) Foreign Application Priority Data
Dec. 18, 2024 (KR) 10-2024-0189740

(51) Int. Cl. G11C 16/14

(52) U.S. Cl. CPC G11C 16/14

(57) ABSTRACT

A memory device includes a memory block including a first cell string and a second cell string having a faster erase speed than the first cell string; and a peripheral circuit configured to perform an erase operation on the memory block, the erase operation including an erase setting operation, an erase execution operation, and a discharge operation, which are sequentially performed, wherein the peripheral circuit is configured to perform the erase execution operation of the first cell string for a first time period, and perform the erase execution operation of the second cell string for a second time period shorter than the first time period.

### CROSS-REFERENCE TO RELATED APPLICATION

The present application claims priority under 35 U.S.C. § 119(a) to Korean patent application number 10-2024-0189740, filed on Dec. 18, 2024, the entire disclosure of which is incorporated herein by reference.

### BACKGROUND

### 1. Technical Field

Various embodiments of the present disclosure generally relate to an electronic device, and more particularly, to a memory device and a method of operating the memory device.

### 2. Related Art

A memory device may include a memory cell array in which data is stored and a peripheral circuit configured to perform a program operation, a read operation, or an erase operation.

The memory device may be configured to perform the program operation, the read operation, or the erase operation in response to a command output from a controller. The erase operation is an operation of erasing data by applying an erase voltage to memory cells of all cell strings included in a selected memory block.

Because memory cells included in the selected memory block may have different electrical characteristics due to manufacturing process limitations, erase speeds of the memory cells included in the selected memory block may be different. During an erase operation for a predetermined period of time, some memory cells may have been erased, while other memory cells might not have been erased. During the erase operation of the memory device, the erase voltage must be continuously applied to the memory block to erase the memory cells that have not been erased. Because the erase voltage is still applied to the erased cell string located in the memory block, an over-erasure phenomenon may occur in the erased cell string. That is, the over-erasure phenomenon is more likely to occur in cell strings having a relatively fast erase speed than in cell strings having a relatively slow erase speed.

The memory cells of the cell string in which the over-erasure occurs may have a lower threshold voltage than the memory cells that are normally erased. During a program operation on a memory block including over-erased memory cells, a time required for the program operation may be increased. A longer program operation time may increase the stress experienced by memory cells, thereby degrading the memory device quickly, and therefore the reliability of the memory device may decrease due to the over-erasure phenomenon.

### SUMMARY

Various embodiments of the present disclosure are directed to a memory device capable of improving the reliability thereof and an operating method thereof.

According to an embodiment of the present disclosure, a memory device may include a memory block including a first cell string and a second cell string having a faster erase speed than the first cell string; and a peripheral circuit configured to perform an erase operation on the memory block, the erase operation including an erase setting operation, an erase execution operation, and a discharge operation, which are sequentially performed, wherein the peripheral circuit is configured to perform the erase execution operation of the first cell string for a first time period, and perform the erase execution operation of the second cell string for a second time period shorter than the first time period.

According to an embodiment of the present disclosure, a memory device may include a memory block including a first cell string and a second cell string having a faster erase speed than the first cell string; and a peripheral circuit configured to perform an erase operation on the memory block, the erase operation including an erase setting operation, an erase execution operation, and a discharge operation, which are sequentially performed, wherein the peripheral circuit is configured to perform the erase setting operation of the second cell string at a later time point than the erase setting operation of the first cell string.

According to an embodiment of the present disclosure, a method of operating a memory device may include adjusting, to a target level, a voltage of a first bit line connected to a first cell string, a voltage of a second bit line connected to a second cell string, and a voltage of a source line connected to the first and second cell strings, the second cell string having a faster erase speed than the first cell string; erasing data of the first and second cell strings; and discharging each of the first bit line, the second bit line, and the source line, wherein the erasing of the data includes erasing the data of the first cell string for a first time period and erasing the data of the second cell string for a second time period shorter than the first time period.

### BRIEF DESCRIPTION OF THE DRAWINGS

FIG. 1 is a diagram illustrating a memory device according to an embodiment of the present disclosure;

FIG. 2 is a diagram illustrating a memory block shown in FIG. 1;

FIG. 3 is a diagram illustrating an arrangement of a memory cell array and a peripheral circuit shown in FIG. 1;

FIG. 4 is a diagram illustrating a first page buffer among a plurality of page buffers of FIG. 1;

FIG. 5 is a diagram illustrating an over-erased memory cell;

FIG. 6A is a diagram illustrating an erase operation of a memory device according to a first embodiment of the present disclosure;

FIG. 6B is a diagram illustrating an erase operation of a memory device according to a second embodiment of the present disclosure;

FIG. 6C is a diagram illustrating an erase operation of a memory device according to a third embodiment of the present disclosure;

FIG. 6D is a diagram illustrating an erase operation of a memory device according to a fourth embodiment of the present disclosure;

FIG. 6E is a diagram illustrating an erase operation of a memory device according to a fifth embodiment of the present disclosure;

FIG. 6F is a diagram illustrating an erase operation of a memory device according to a sixth embodiment of the present disclosure;

FIG. 7 is a diagram illustrating a memory card system to which a memory device according to an embodiment of the present disclosure is applied; and

FIG. 8 is a diagram illustrating a Solid-State Drive (SSD) system to which a memory device according to an embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure can be implemented in various forms and replaced with other equivalent embodiments, and they should not be construed as being limited to the specific embodiments set forth herein.

Hereinafter, the terms such as “first” and “second” may be used to describe various components. However, the components should not be limited by these terms. The above terms are used to distinguish one component from another component.

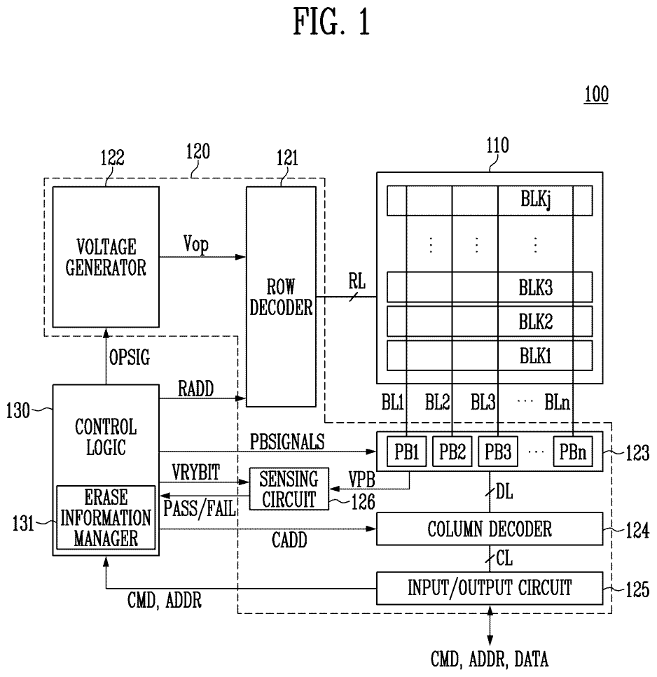

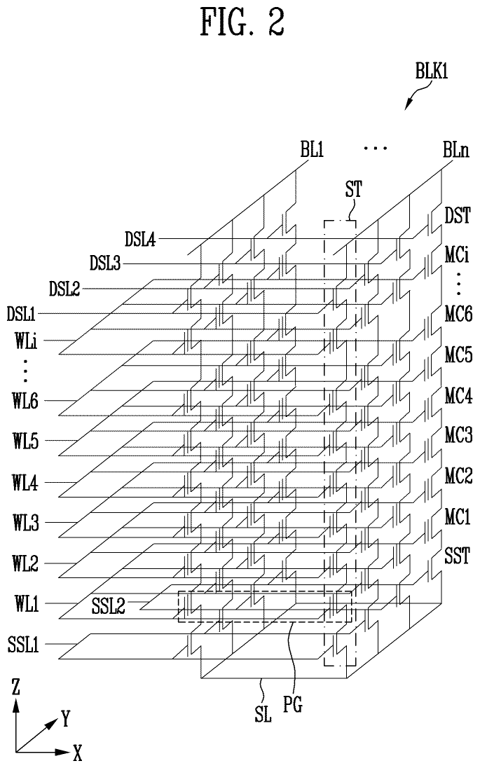

FIG. 1 is a diagram illustrating a memory device 100 according to an embodiment of the present disclosure. FIG. 2 is a diagram illustrating a memory block illustrated in FIG. 1.

Referring to FIGS. 1 and 2, the memory device 100 may include a memory cell array 110, a peripheral circuit 120, and control logic 130.

The memory cell array 110 includes first to j-th memory blocks BLK1 to BLKj. The first to j-th memory blocks BLK1 to BLKj are connected to a row decoder 121 through row lines RL. The first to j-th memory blocks BLK1 to BLKj may be connected to a page buffer group 123 through bit lines BL1 to BLn. Each of the first to j-th memory blocks BLK1 to BLKj includes a plurality of cell strings ST, and each of the plurality of cell strings ST includes a plurality of memory cells. In an embodiment, the plurality of memory cells are non-volatile memory cells. Memory cells connected to the same word line may be defined as a single page PG. Thus, one memory block may include a plurality of pages.

The first to j-th memory blocks BLK1 to BLKj may be configured to be identical to each other, and the structure of the first memory block BLK1, for example, is described in detail below.

In FIG. 2, the first memory block BLK1 includes the cell strings ST connected between the first to n-th bit lines BL1 to BLn and a source line SL. Because the first to n-th bit lines BL1 to BLn extend in a Y direction and are arranged spaced apart from each other in an X direction, the cell strings ST may also be arranged spaced apart in the X and Y directions. For example, the cell strings ST may be connected between the first bit line BL1 and the source line SL, and the cell strings ST may be arranged between the second bit line BL2 and the source line SL. In this way, the cell strings ST may be arranged between the n-th bit line BLn and the source line SL. The cell strings ST may extend in a Z direction.

When one of the cell strings ST connected to the n-th bit line BLn is described as an example, the cell string ST may include a source select transistor SST, first to i-th memory cells MC1 to MCi, and a drain select transistor DST. Because the first memory block BLK1 shown in FIG. 2 is a diagram schematically illustrating the structure of the memory block, the number of the source select transistors SST, the first to i-th memory cells MC1 to MCi, and the drain select transistors DST included in the cell strings ST may be changed according to the memory device.

Gates of the source select transistors SST included in different cell strings may be connected to a first or second source select line SSL1 or SSL2, gates of the first to i-th memory cells MC1 to MCi may be connected to first to i-th word lines WL1 to WLi, and each of gates of the drain select transistors DST may be connected to one of first to fourth drain select lines DSL1 to DSL4.

To describe the lines connected to the first memory block BLK1 in more detail, the source select transistors SST arranged in the X direction may be connected to the same source select line as each other, and the source select transistors SST arranged in the Y direction may be connected to source select lines separated from each other. For example, some of the source select transistors SST arranged in the Y direction may be connected to the first source select line SSL1, and the remaining source select transistors SST other than some source select transistors SST may be connected to the second source select line SSL2. The second source select line SSL2 is separated from the first source select line SSL1. Thus, a voltage applied to the first source select line SSL1 may be the same as or different from a voltage applied to the second source select line SSL2.

Memory cells formed in the same level among the first to i-th memory cells MC1 to MCi may be connected to the same word line. For example, the first memory cells MC1 included in different cell strings ST may be connected in common to the first word line WL1, and the i-th memory cells MCi included in different cell strings ST may be connected in common to the i-th word line WLi. The group of memory cells included in different cell strings ST and connected to the same word line forms the page PG. Program and read operations may be performed in units of pages PG, and pre-program and erase operations may be performed in units of memory blocks. Operations performed in units of memory blocks may be performed on all pages included in a selected memory block.

The drain select transistors DST arranged in the Y direction may be connected to the first to fourth drain select lines DSL1 to DSL4 separated from each other. Specifically, the drain select transistors DST arranged in the X direction may be connected to the same drain select line as each other, and the drain select transistors DST arranged in the Y direction may be connected to the first to fourth drain select lines DSL1 to DSL4 separated from each other. Because the first to fourth drain select lines DSL1 to DSL4 are separated from each other, different voltages may be applied to the first to fourth drain select lines DSL1 to DSL4.

Referring to FIGS. 1 and 2, the row lines RL may include the source select lines SSL1 and SSL2, the plurality of word lines WL1 to WLi, and the drain select lines DSL1 to DSL4. The source select lines SSL1 and SSL2, the plurality of word lines WL1 to WLi, and the drain select lines DSL1 to DSL4 may be connected to each of the first to j-th memory blocks BLK1 to BLKj. Each of the bit lines BL1 to BLn may be connected to at least one cell string.

Memory cells included in the memory cell array 110 may be programmed in a Multi-Level Cell (MLC) method, a Triple-Level Cell (TLC) method, or a Quad-Level Cell (QLC) method depending on the number of bits of data stored. Each of the memory cells programmed in the MLC method may store two bits of data. Each of the memory cells programmed in the TLC method may store three bits of data. Each of the memory cells programmed in the QLC method may store four bits of data. The methods in which the memory cells are programmed may be set differently depending on a memory device. In addition to the methods described above, a method of programming five bits or more of data in one memory cell may be used.

The peripheral circuit 120 may be configured to perform a program operation, a read operation, or an erase operation on a selected area of the memory cell array 110 under the control of the control logic 130. For example, the peripheral circuit 120 may apply various operating voltages to the row lines RL and the first to n-th bit lines BL1 to BLn, or selectively discharge the row lines RL and the first to n-th bit lines BL1 to BLn under the control of the control logic 130.

The peripheral circuit 120 may include the row decoder 121, a voltage generator 122, the page buffer group 123, a column decoder 124, an input and output (input/output) circuit 125, and a sensing circuit 126.

The row decoder 121 is connected to the memory cell array 110 through the row lines RL. The row lines RL may include at least one source select line, a plurality of word lines, and at least one drain select line. In an embodiment, the word lines may include normal word lines and dummy word lines.

The row decoder 121 is configured to decode a row address RADD received from the control logic 130. The row decoder 121 selects at least one of the memory blocks BLK1 to BLKj according to the decoded address. In addition, the row decoder 121 may transfer operating voltages Vop generated by the voltage generator 122 to the row lines RL of the selected memory block according to the decoded address.

For example, during a program operation, the row decoder 121 may apply a program voltage to a selected word line and apply, to unselected word lines, a program pass voltage at a level less than that of the program voltage. During a program verify operation, the row decoder 121 may apply a verify voltage to the selected word line and apply, to the unselected word lines, a verify pass voltage at a level greater than that of the verify voltage. During a read operation, the row decoder 121 may apply a read voltage to the selected word line and apply, to the unselected word lines, a read pass voltage at a level greater than that of the read voltage.

An erase operation of the memory device 100 is performed in units of memory blocks. During the erase operation, the row decoder 121 may select one memory block according to the decoded address. During the erase operation, the row decoder 121 may apply a voltage of 0 V or a ground voltage to word lines connected to the selected memory block, or cause the word lines to float.

The voltage generator 122 operates in response to the control of the control logic 130. The voltage generator 122 is configured to generate a plurality of voltages using an external power voltage supplied to the memory device 100. Specifically, the voltage generator 122 may generate the various operating voltages Vop used for the program, read, and erase operations in response to an operating signal OPSIG generated by the control logic 130. For example, the voltage generator 122 may generate a program voltage, a verify voltage, a pass voltage, a read voltage, an erase voltage, and the like in response to the control of the control logic 130.

The page buffer group 123 includes first to n-th page buffers PB1 to PBn. The first to n-th page buffers PB1 to PBn are connected to the memory cell array 110 through the first to n-th bit lines BL1 to BLn. The first to n-th page buffers PB1 to PBn operate in response to the control of the control logic 130. Specifically, the first to n-th page buffers PB1 to PBn may operate in response to page buffer control signals PBSIGNALS. For example, the first to n-th page buffers PB1 to PBn may temporarily store data received through the first to n-th bit lines BL1 to BLn, or sense a voltage or current of the first to n-th bit lines BL1 to BLn during the read or verify operation.

Specifically, during the program operation, when the program voltage is applied to the selected word line, the first to n-th page buffers PB1 to PBn may transfer data DATA received through the input/output circuit 125 to selected memory cells through the first to n-th bit lines BL1 to BLn. Memory cells of a selected page are programmed according to the transferred data DATA. During the program verify operation, the first to n-th page buffers PB1 to PBn sense the voltage or current received from the selected memory cells through the first to n-th bit lines BL1 to BLn to read page data.

During the read operation, the first to n-th page buffers PB1 to PBn read the data DATA from the memory cells of the selected page through the first to n-th bit lines BL1 to BLn, and output the read data DATA to the input/output circuit 125 under the control of the column decoder 124.

During the erase operation, the first to n-th page buffers PB1 to PBn may float the first to n-th bit lines BL1 to BLn or apply the erase voltage to the first to n-th bit lines BL1 to BLn.

The column decoder 124 may transfer data between the input/output circuit 125 and the page buffer group 123 in response to a column address CADD. For example, the column decoder 124 may exchange data with the first to n-th page buffers PB1 to PBn through data lines DL, or exchange data with the input/output circuit 125 through column lines CL.

The input/output circuit 125 may transfer, to the control logic 130, a command CMD and an address ADDR received from a memory controller, or may exchange the data DATA with the column decoder 124.

During the read operation or the verify operation, the sensing circuit 126 may generate a reference current in response to an allowable bit VRYBIT signal, and compare a sensing voltage VPB received from the page buffer group 123 with a reference voltage generated by the reference current to output a pass signal PASS or a fail signal FAIL.

The control logic 130 may output the operation signal OPSIG, the row address RADD, the page buffer control signals PBSIGNALS, and the allow bit VRYBIT in response to the command CMD and the address ADDR to control the peripheral circuit 120. For example, the control logic 130 may control the read operation of the selected memory block in response to a sub-block read command and address. Further, the control logic 130 may control the erase operation of the selected sub-block included in the selected memory block in response to the sub-block erase command and address. In addition, the control logic 130 may determine whether the verify operation has passed or failed in response to the pass or fail signal PASS or FAIL.

The control logic 130 includes an erase information manager 131 which stores erase operation-related information.

The erase information manager 131 may store and update at least one piece of erase operation-related information among erase speed information, discharge voltage information, erase setting operation timing information, erase execution operation timing information, and discharge operation timing information for a cell string or a cell string group. The erase information manager 131 may store the erase operation-related information for each memory block. The control logic 130 may control the erase operation according to the information stored in the erase information manager 131 during the erase operation.

The erase speed information may include information on a speed at which a cell string or a cell string group for each memory block is erased. The erase speed information may be an initial set value for the cell string or the cell string group for each memory block. Alternatively, the erase speed information may be speed information measured through the verify operation after the shallow erase or may be updated information.

The discharge voltage information may mean information on a discharge voltage for each cell string. For example, the discharge voltage information may include information on the discharge voltage during a discharge operation on a first cell string of which an erase speed is slower than a reference speed and information on the discharge voltage during the discharge operation on a second cell string of which an erase speed is faster than the reference speed. The discharge voltage information may be an initial set value or information measured and stored through the verify operation after the shallow erase or may be updated information.

The erase setting operation timing information may include timing information of performing an erase setting operation in which the erase voltage is applied to the cell string to rise to a target potential. For example, the erase setting operation timing information may include information on an erase setting operation time point for the first cell string of which the erase speed is slower than the reference speed, and information on an erase setting operation time point for the second cell string of which the erase speed is faster than the reference speed.

The erase execution operation timing information may include timing information at which an erase execution operation for each cell string is performed. For example, the erase execution operation timing information may include information on an erase execution operation time point of the first cell string of which the erase speed is slower than the reference speed, and information on an erase execution operation time point of the second cell string of which the erase speed is faster than the reference speed.

The discharge operation timing information may include timing information at which the discharge operation for each cell string is performed. For example, the discharge time for a bit line connected to the second cell string of which the erase speed is faster than the reference speed may be set to a point in time earlier than the discharge time for a bit line connected to the first cell string of which the erase speed is slower than the reference speed.

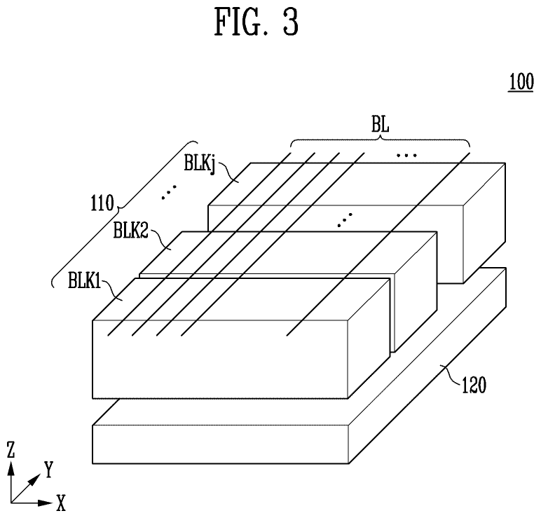

FIG. 3 is a diagram illustrating an arrangement of the memory cell array 110 and the peripheral circuit 120 shown in FIG. 1.

Referring to FIG. 3, the peripheral circuit 120 and the memory cell array 110 may be included in the memory device 100 of FIG. 1. The peripheral circuit 120 may be arranged over a substrate, and the memory cell array 110 may be arranged over the peripheral circuit 120. The memory cell array 110 may include the first to j-th memory blocks BLK1 to BLKj. A plurality of bit lines BL may be arranged over the first to j-th memory blocks BLK1 to BLKj.

The plurality of bit lines BL may be arranged spaced apart from each other in the X direction and may extend in the Y direction. The first to j-th memory blocks BLK1 to BLKj may be arranged spaced apart from each other in the Y direction. The first to j-th memory blocks BLK1 to BLKj may be configured to be identical to each other.

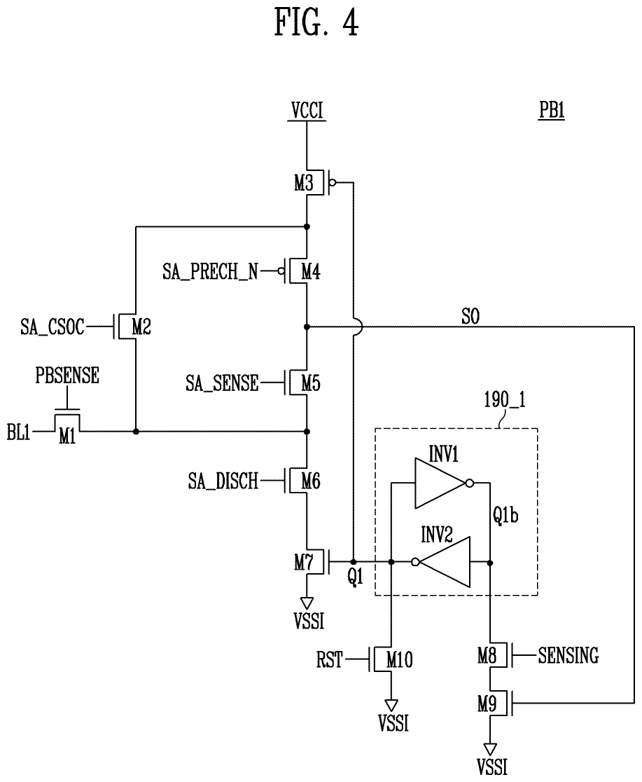

FIG. 4 is a diagram illustrating the first page buffer PB1 among the plurality of page buffers PB1 to PBn of FIG. 1. Although not shown in FIG. 4, the second to n-th page buffers PB2 to PBn may also be implemented in the same structure as in FIG. 4. The circuit shown in FIG. 4 represents a part of the first page buffer PB1, and the configuration may be changed depending on a memory device.

Referring to FIG. 1 and FIG. 4, the first page buffer PB1 is connected to the first memory cell MC1 through the first bit line BL1, and may perform a bit line precharge operation of charging a charge supplied from an internal power voltage VCCI to the first bit line BL1 through first to fifth transistors M1 to M5. The first transistor M1 is controlled by a first sense signal PBSENSE. The second transistor M2 may be implemented as an N-type transistor controlled by a first precharge signal SA_CSOC. The third transistor M3 may be implemented as a P-type transistor controlled by data stored in a latch 190_1. The fourth transistor M4 may be implemented as an N-type transistor controlled by a second precharge signal SA_PRECH_N. The fifth transistor M5 may be implemented as an N-type transistor controlled by a second sense signal SA_SENSE.

In addition, the first page buffer PB1 may discharge the charge charged to the first bit line BL1 through the first transistor M1, a sixth transistor M6, and a seventh transistor M7 to a terminal for an internal ground voltage VSSI. The sixth transistor M6 may be implemented as an N-type transistor controlled by a first discharge signal SA_DISCH. The seventh transistor M7 may be implemented as an N-type transistor controlled by data stored in the latch 190_1.

In an embodiment, the first page buffer PB1 may include the latch 190_1 including a first inverter INV1 and a second inverter INV2 coupled in parallel between a main node Q1 and an inverting node Q1b. The first page buffer PB1 may further include a plurality of latches in addition to the latch 190_1. The latch 190_1 may control the bit line precharge operation by turning on or off the third transistor M3 through the main node Q1. The inverting node Q1b and the main node Q1 may store data that is inverted from each other.

The fourth transistor M4 and the fifth transistor M5 may be coupled to a sensing node SO. A voltage of the sensing node SO during a sensing operation on the first memory cell MC1 is determined based on a threshold voltage of the first memory cell MC1. The latch 190_1 may store a result of sensing the threshold voltage of the first memory cell MC1 through a ninth transistor M9 connected to the sensing node SO. The ninth transistor M9 may be an N-type transistor, and the sensing node SO may be connected to a gate node of the ninth transistor M9. The tenth transistor M10, which connects the main node Q1 to VSSI, is turned on by a reset signal RST, and the eighth transistor M8, which connects the inverting node Q1b to the ninth transistor M9, can be turned on by a sensing signal SENSING.

During a verify operation of the first memory cell MC1, the sensing node SO and the first bit line BL1 may be precharged to a positive voltage level, and a voltage of the first bit line BL1 may be changed or maintained according to the threshold voltage of the first memory cell MC1. When the fifth transistor M5 is turned on, because the voltage of the first bit line BL1 is transferred to the sensing node SO, a voltage of the sensing node SO may be changed or maintained according to the voltage of the first bit line BL1.

When the threshold voltage of the first memory cell MC1 is less than a verify voltage, the first memory cell MC1 is turned on, so that the voltage of the first bit line BL1 may be less than a precharge voltage, and a potential of the sensing node SO may transition to a low state less than a reference voltage. Therefore, the ninth transistor M9 may be turned off. When the threshold voltage of the first memory cell MC1 is greater than the verify voltage, because the first memory cell MC1 is turned off, the voltage of the first bit line BL1 may be maintained at the precharge voltage, and the potential of the sensing node SO may be maintained at a high state greater than the reference voltage. Thus, the ninth transistor M9 may be turned on. The configuration of the first page buffer PB1 may vary depending on a memory device.

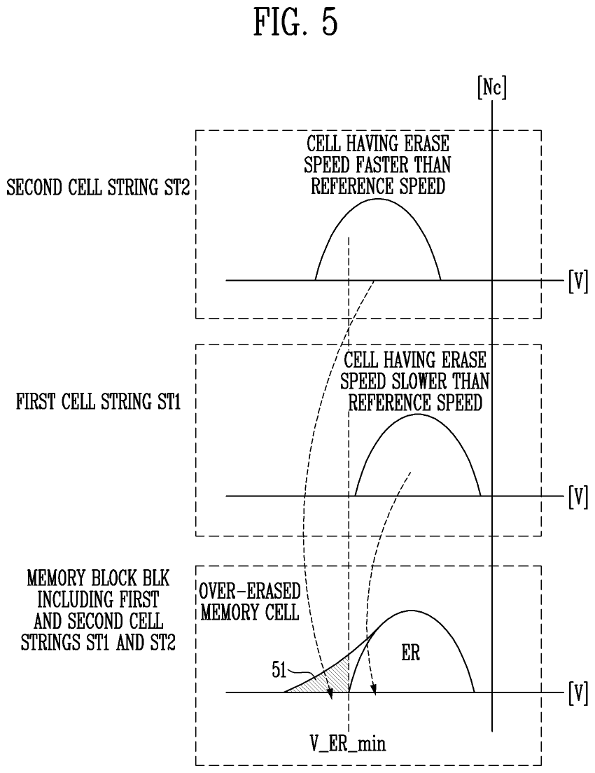

FIG. 5 is a diagram illustrating an over-erased memory cell.

Referring to FIG. 5, the horizontal axis represents a threshold voltage V, and the vertical axis represents the number of memory cells Nc. When an erase operation is performed, threshold voltages of the memory cells may be lowered by an erase voltage. A reference threshold voltage V_ER_min may be the minimum value of a threshold voltage distribution corresponding to an erase state ER. Memory cells 51 having a threshold voltage less than the reference erase distribution V_ER_min may be determined to be over-erased memory cells.

The difference in erase speed between cell strings may be one of the reasons why memory cells are over-erased. A second cell string ST2 of which an erase speed is faster than a reference speed is more likely to be over-erased than a first cell string ST1 of which an erase speed is slower than the reference speed.

Among a plurality of cell strings arranged in a memory block, the second cell strings ST2 arranged in the edge portion of the memory block may generate a larger amount of gate induced drain leakage (GIDL) than the first cell strings ST1 arranged in the center portion of the memory block. An erase speed of a memory cell having a large amount of GIDL generation may be faster than an erase speed of a memory cell having a small amount of GIDL generation. Therefore, in the erase operation, the second cell string ST2, which generates a large amount of GIDL, is more likely to be over-erased than the first cell string ST1.

Also, the second cell string ST2 that is closer to the row decoder 121 than the first cell string ST1 may have a faster erase speed than the first cell string ST1 that is farther from the row decoder 121 than the second cell string ST2. Therefore, during the erase operation, the second cell string ST2 which is closer to the row decoder 121 than the first cell string ST1 is more likely to be over-erased than the first cell string ST1 that is farther from the row decoder 121 than the second cell string ST2.

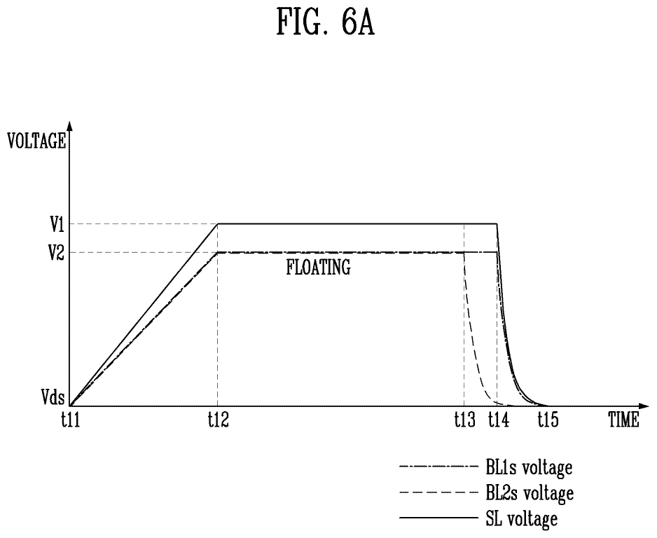

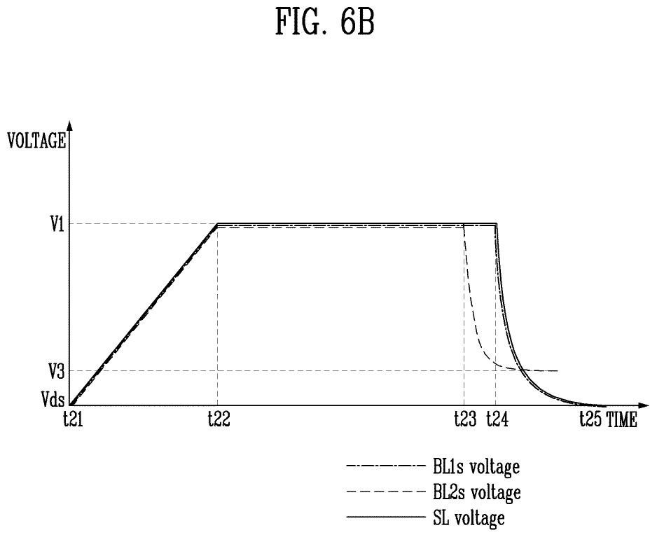

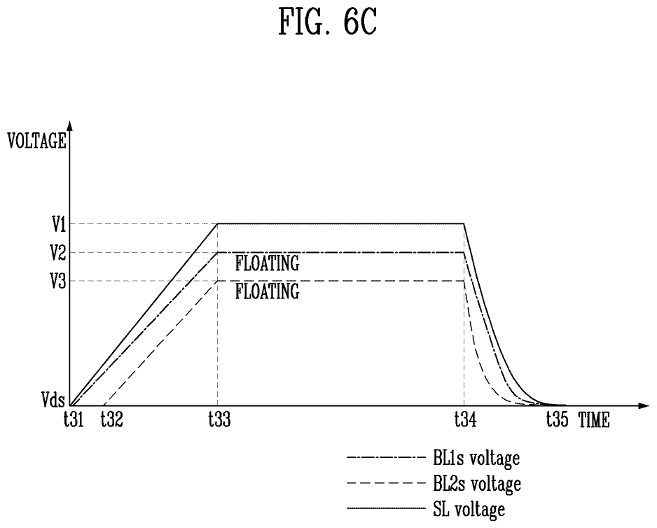

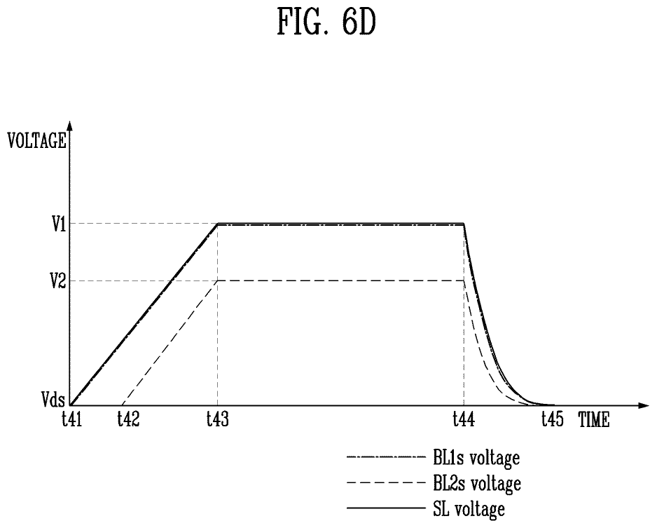

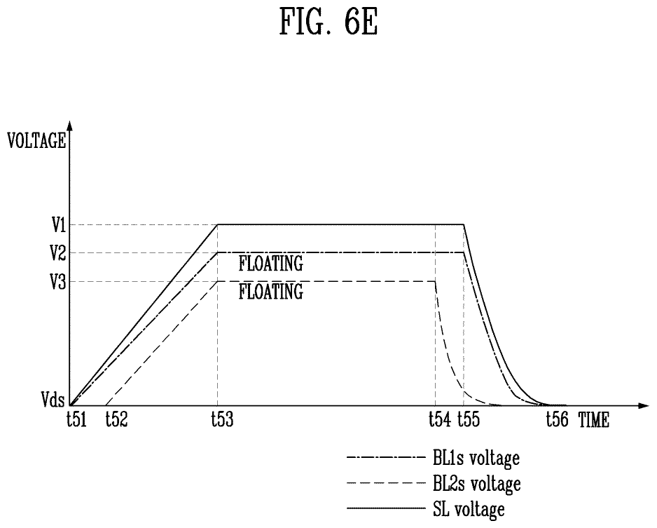

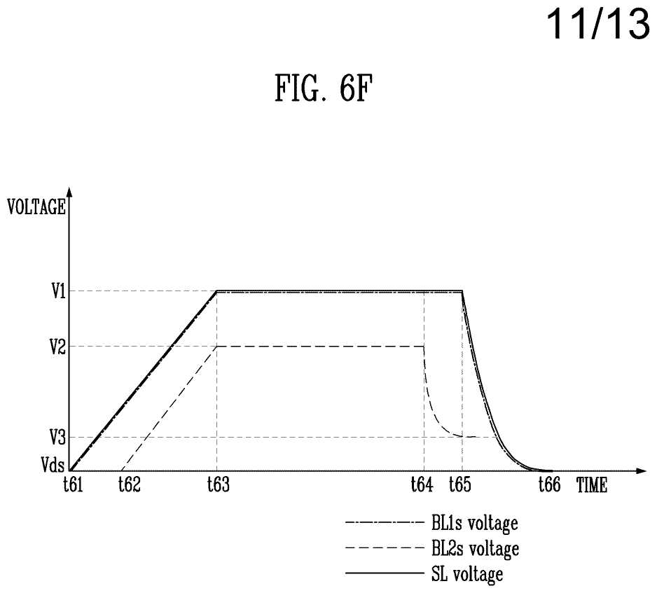

FIGS. 6A to 6F are diagrams illustrating an erase operation of a memory device according to first to sixth embodiments of the present disclosure.

In FIGS. 6A to 6F, the erase operation includes an erase setting operation, an erase execution operation, and a discharge operation. Embodiments focus on the erase operation, and a description of an erase verify operation after the erase operation is omitted.

The erase setting operation refers to an operation of applying an erase voltage to the bit line BL in FIG. 2 and the source line SL in FIG. 2 to increase voltages of the bit line BL and the source line SL to a first target level. The erase execution operation refers to a process of erasing data of a plurality of cell strings of a memory block with erase voltages of the bit line BL and the source line SL increased to the first target level. The discharge operation refers to an operation of decreasing the erase voltages of the bit line BL and the source line SL, which are increased to the first target level, to a second target level.

For convenience, a cell string of which an erase speed is slower than a reference speed among the cell strings is the first cell string ST1, and a cell string of which an erase speed is faster than the reference speed is the second cell string ST2. That is, the first cell string ST1 may be a cell string having a relatively slow erase speed, and the second cell string ST2 may be a cell string having a relatively fast erase speed. The first cell string ST1 may refer to memory cells of the first cell string ST1, and the second cell string ST2 may refer to memory cells of the second cell string ST2.

Each of the first cell string ST1 and the second cell string ST2 may mean a plurality of cell strings. In addition to the first and second cell strings ST1 and ST2 among the plurality of cell strings, there may also be cell strings having other erase speeds. Further, the plurality of cell strings may be divided into a first cell string ST1 group including cell strings of which an erase speed is slower than a reference erase speed, and a second cell string ST2 group including cell strings of which an erase speed is faster than the reference erase speed. Thus, in embodiments described below, the first cell string ST1 may be a single first cell string or a plurality of first cell strings, and the second cell string ST2 may also be a single second cell string or a plurality of second cell strings. A bit line connected to the first cell string ST1 is a first speed bit line BL1s, and a bit line connected to the second cell string ST2 is a second speed bit line BL2s.

The peripheral circuit 120 FIG. 1 performs the erase operation on the first cell string ST1 and the second cell string ST2 under the control of the control logic 130.

FIG. 6A is a diagram illustrating an erase operation of the memory device 100 according to a first embodiment of the present disclosure.

Referring to FIG. 6A, the peripheral circuit 120 of FIG. 1 may perform an erase setting operation on the first and second cell strings ST1 and ST2 from a first time point t11 to a second time point t12.

Specifically, the peripheral circuit 120 may float the first and second speed bit lines BL1s and BL2s from the first time point t11 to the second time point t12, and raise a potential of the source line SL to a first target level V1. Because the first and second speed bit lines BL1s and BL2s are in a floating state, potentials of the first and second speed bit lines BL1s and BL2s may rise together as the potential of the source line SL rises. For example, the potentials of the first and second speed bit lines BL1s and BL2s may rise to a second target level V2 less than the first target level V1 of the source line SL.

While the voltage of the source line SL rises to the first target level V1, GIDL may occur in source select transistors. While the voltages of the first and second speed bit lines BL1s and BL2s rise to the second target level V2, GIDL may also occur in drain select transistors.

When the erase setting operation is completed, the peripheral circuit 120 may perform an erase execution operation on the first cell string ST1 from the second time point t12 to a fourth time point t14. Then, the peripheral circuit 120 may perform the erase execution operation on the second cell string ST2 from the second time point t12 to a third time point t13.

During the erase execution operation, data of memory cells included in the first and second cell strings ST1 and ST2 may be erased. The first and second speed bit lines BL1s and BL2s connected to the first and second cell strings ST1 and ST2 then remain in a floating state.

The potential of the source line SL may be maintained at the first target level V1 from the second time point t12 at which the erase execution operation on the first cell string ST1 starts to the fourth time point t14 at which the erase execution operation ends. Further, the potential of the source line SL may be maintained at the first target level V1 from the second time point t12 at which the erase execution operation on the second cell string ST2 starts to the third time point t14 at which the erase execution operation ends. In addition, floating potentials of the first and second speed bit lines BL1s and BL2s connected to the first and second cell strings ST1 and ST2, respectively, may be maintained at the second target level V2 less than the first target level V1.

When the erase execution operation is completed, the peripheral circuit 120 may perform a discharge operation on the second speed bit line BL2s connected to the second cell string ST2 from the third time point t13. Then, the peripheral circuit 120 may perform the discharge operation on the first speed bit line BL1s connected to the first cell string ST1 and the source line SL from the fourth time point t14.

For example, when the erasure of the memory cells included in the first and second cell strings ST1 and ST2 is completed, the peripheral circuit 120 may decrease the potential of the source line SL to a discharge level Vds, and decrease the potentials of the first and second speed bit lines BL1s and BL2s to the discharge level Vds.

In one type of memory device that has been proposed, even when the erasure of the second cell string ST2 having a relatively fast erase speed is completed first, the peripheral circuit 120 simultaneously performs a discharge operation on the first and second cell strings ST1 and ST2 from a time point at which the erasure of the first cell string ST1 having a relatively slow erase speed is completed. Therefore, while the erase operation of the first cell string ST1 is performed, an over-erasure phenomenon may occur in the second cell string ST2 that has already been erased.

To prevent or mitigate an over-erasure phenomenon occurring in the second cell string ST2, the memory device 100 of FIG. 1 of the first embodiment may perform the discharge operation on the second speed bit line BL2s connected to the second cell string ST2 of which the erase speed is faster than a reference speed at an earlier time point than the discharge operation on the first speed bit line BL1s connected to the first cell string ST1 of which the erase speed is slower than the reference speed. An erase potential of the source line SL is discharged together at the point in time of discharging the first speed bit line BL1s.

In the memory device 100 of FIG. 1 according to the first embodiment, during the erase operation of the memory block, the peripheral circuit 120 may perform the erase execution operation of the second speed bit line BL2s connected to the second cell string ST2 having the erase speed faster than that of the first cell string ST1 for a shorter time period than the erase execution operation of the first speed bit line BL1s connected to the first cell string ST1, so that the occurrence of the over-erasure phenomenon of the second cell string ST2 may be prevented or mitigated.

FIG. 6B is a diagram illustrating an erase operation of the memory device 100 according to a second embodiment of the present disclosure.

Referring to FIG. 6B, the peripheral circuit 120 of FIG. 1 may perform an erase setting operation on the first and second cell strings ST1 and ST2 from a first time point t21 to a second time point t22.

Specifically, the peripheral circuit 120 may apply an erase voltage to the first and second speed bit lines BL1s and BL2s and the source line SL from the first time point t21 to the second time point t22. Accordingly, within an erase setting operation period, potentials of the first speed bit line BL1s, the second speed bit line BL2s, and the source line SL may be increased from the discharge level Vds to the first target level V1.

During the erase setting operation, the first and second speed bit lines BL1s and BL2s are not in a floating state. During the erase setting operation, the potentials of the first and second speed bit lines BL1s and BL2s may be of the same magnitude as the potential of the source line SL.

The peripheral circuit 120 may perform an erase execution operation on the first cell string ST1 from the second time point t22 to a fourth time point t24, and may perform the erase execution operation on the second cell string ST2 from the second time point t22 to a third time point t23.

Specifically, the peripheral circuit 120 may apply the erase voltage to the first speed bit line BL1s, the second speed bit line BL2s, and the source line SL during the erase execution operation. Therefore, during the erase execution operation, potentials of the first speed bit line BL1s, the second speed bit line BL2s, and the source line SL may all be maintained at the first target level V1.

The peripheral circuit 120 may perform a discharge operation on the second speed bit line BL2s at the third time point t23 that is earlier than the fourth time point t24 at which the discharge operation on the first speed bit line BL1s is performed. Therefore, a time required for the erase execution operation on the second cell string ST2 may be shorter than that for the erase execution operation on the first cell string ST1.

The peripheral circuit 120 may discharge the potential of the first speed bit line BL1s to the discharge level Vds, and discharge the potential of the second speed bit line BL2s to a third target level V3 greater than the discharge level Vds. That is, the peripheral circuit 120 may maintain a voltage of the second speed bit line BL2s after the discharge operation to be greater than a voltage of the first speed bit line BL1s after the discharge operation.

The memory device 100 of the second embodiment performs the discharge operation of the second speed bit line BL2s connected to the second cell string ST2 having a relatively fast erase speed at an earlier time point than the discharge operation of the first speed bit line BL1s connected to the first cell string ST1 having a relatively slow erase speed. A voltage of the source line SL is also discharged at the time of discharging the first cell string ST1. Therefore, the peripheral circuit 120 may perform the erase execution operation on the second cell string ST2 having a relatively high erase speed for a shorter time than the erase execution operation on the first cell string ST1, thereby preventing or mitigating the occurrence of an over-erasure phenomenon of the second cell string ST2.

FIG. 6C is a diagram illustrating an erase operation of the memory device 100 according to a third embodiment of the present disclosure.

Referring to FIG. 6C, the peripheral circuit 120 of FIG. 1 may perform an erase setting operation on the first cell string ST1 from a first time point t31 to a third time point t33, and may perform the erase setting operation on the second cell string ST2 from a second time point t32 to the third time point t33.

A voltage of the source line SL may rise from the discharge level Vds at the first time point t31 to the first target level V1 at the third time point t33 by receiving an erase voltage.

During the erase setting operation, the first and second speed bit lines BL1s and BL2s are floating, and floating potentials of the first and second speed bit lines BL1s and BL2s may rise together as the voltage of the source line SL rises.

The second speed bit line BL2s may float later than the first speed bit line BL1s. The floating potential of the first speed bit line BL1s may rise from the discharge level Vds at the first time point t31 to the second target level V2 at the third time point t33. The floating potential of the second speed bit line BL2s may rise from the discharge level Vds at the second time point t32 to the third target level V3 at the third time point t33.

The floating potential of the first speed bit line BL1s floating ahead of the second speed bit line BL2s rises ahead of the floating potential of the second speed bit line BL2s. Thus during the erase operation, the floating potential of the first speed bit line BL1s is greater than that of the second speed bit line BL2s.

The peripheral circuit 120 may perform an erase execution operation on the first and second cell strings ST1 and ST2 from the third time point t33 to the fourth time point t34.

In the erase execution operation, the floating potential of the second speed bit line BL2s is at the third target level V3, and the floating potential of the first speed bit line BL1s is at the second target level V2. That is, in the erase execution operation, the peripheral circuit 120 performs the erase execution operation on the second cell string ST2 with a bit line floating potential less than that of the first cell string ST1.

Unlike the embodiments described above having characteristics that the time point at which the first speed bit line BL1s is discharged is different from that at which the second speed bit line BL2s is discharged, the peripheral circuit 120 of the third embodiment may simultaneously perform the discharge operation on the first and second cell strings ST1 and ST2 from the fourth time point t34. For example, the peripheral circuit 120 may lower potentials of the first and second speed bit lines BL1s and BL2s and the source line SL to the discharge level Vds from the fourth time point t34.

The memory device 100 according to the third embodiment may perform the erase execution operation on the second cell string ST2 at a lower floating potential than the first cell string ST1 by performing the erase setting operation on the second cell string ST2 having a relatively fast erase speed at a time point later than the erase setting operation on the first cell string ST1 having a relatively slow erase speed. Therefore, an over-erasure phenomenon due to the erase operation of the second cell string ST2 having a high erase speed may be prevented or mitigated.

FIG. 6D is a diagram illustrating an erase operation of the memory device 100 according to a fourth embodiment of the present disclosure.

Referring to FIG. 6D, the peripheral circuit 120 of FIG. 1 may perform an erase setting operation on the first cell string ST1 from a first time point t41 to a third time point t43, and may perform the erase setting operation on the second cell string ST2 from a second time point t42 to the third time point t43.

The control logic 130 may apply an erase voltage to the source line SL and the first and second speed bit lines BL1s and BL2s to raise a potential of each of the source line SL and the first and second speed bit lines BL1s and BL2s.

Specifically, the potentials of the source line SL and the first speed bit line BL1s are at the discharge level Vds at the first time point t41 and the first target level V1 at the third time point t43. The potential of the second speed bit line BL2s is at the discharge level Vds at the second time point t42 and the second target level V2 at the third time point t43.

That is, the peripheral circuit 120 may start the erase setting operation of the second cell string ST2 having a relatively fast erase speed at a time later than the erase setting operation of the first cell string ST1 having a relatively slow erase speed. Therefore, at the third time point t43 at which the erase setting operation of the first and second cell strings ST1 and ST2 is completed, the second speed bit line BL2s may have the potential less than the potential of the first speed bit line BL1s.

The peripheral circuit 120 may perform an erase execution operation on the first and second cell strings ST1 and ST2 from the third time point t43 to a fourth time point t44.

During the erase execution operation, the peripheral circuit 120 may maintain a voltage of the source line SL at the first target level V1 and the potential of the first speed bit line BL1s at the first target level V1. The peripheral circuit 120 may maintain the potential of the second speed bit line BL2s at the second target level V2. The peripheral circuit 120 may perform the erase execution operation on the first cell string ST1 at the first target level V1, and perform the erase execution operation on the second cell string ST2 at the second target level V2 less than the first target level V1. That is, during the erase execution operation, the peripheral circuit 120 may erase the second cell string ST2 at a lower potential than the first cell string ST1, thereby preventing or mitigating the occurrence of an over-erasure phenomenon of the second cell string ST2.

The peripheral circuit 120 may perform a discharge operation on the first and second cell strings ST1 and ST2 from the fourth time point t44 to a fifth time point t45. That is, the peripheral circuit 120 may perform the discharge operation from the fourth time point t44 to lower voltages of the source line SL and the first and second speed bit lines BL1s and BL2s to the discharge level Vds.

The memory device 100 according to the fourth embodiment may erase the second cell string ST2 with a lower erase voltage than the first cell string ST1 by performing the erase setting operation of the second cell string ST2 having a high erase speed at a time point later than the erase setting operation of the first cell string ST1 having a low erase speed. Accordingly, the second cell string ST2 is erased with a lower voltage than the first cell string ST1, so that the occurrence of an over-erasure phenomenon of the second cell string ST2 may be prevented or mitigated.

FIG. 6E is a diagram illustrating an erase operation of the memory device 100 according to a fifth embodiment of the present disclosure.

Referring to FIG. 6E, the peripheral circuit 120 of FIG. 1 may perform an erase setting operation on the first cell string ST1 from a first time point t51 to a third time point t53, and may perform the erase setting operation on the second cell string ST2 from a second time point t52 to the third time point t53.

A potential of the source line SL may rise to the first target level V1 at the third time point t53 by receiving an erase voltage from the discharge level Vds at the first time point t51.

During the erase setting operation, the first and second speed bit lines BL1s and BL2s are floated, and floating potentials may rise together as the potential of the source line SL rises. The second speed bit line BL2s of the second cell string ST2 having a relatively fast erase speed may be floated at a later time point than the first speed bit line BL1s connected to the first cell string ST1 having a relatively slow erase speed.

A floating voltage of the first speed bit line BL1s may rise from the discharge level Vds at the first time point t51 to the second target level V2 at the third time point t53. A floating potential of the second speed bit line BL2s may rise from the discharge level Vds at the second time point t52 to the third target level V3 at the third time point t53.

That is, because the floating potential of the first speed bit line BL1s floating earlier rises before the floating potential of the second speed bit line BL2s, the floating potential of the first speed bit line BL1s remains greater than the floating potential of the second speed bit line BL2s during the erase operation.

When the erase setting operation is completed, the peripheral circuit 120 may perform an erase execution operation on the first cell string ST1 from the third time point t53 to a fifth time point t55. Then, the peripheral circuit 120 may perform the erase execution operation on the second cell string ST2 from the third time point t53 to a fourth time point t54.

During the erase execution operation, data of memory cells included in the first and second cell strings ST1 and ST2 may be erased. The first and second speed bit lines BL1s, BL2s remain floating. During the erase execution operation, the floating voltage of the first speed bit line BL1s may be maintained at the second target level V2, and a floating voltage of the second speed bit line BL2s may be maintained the third target level V3 less than the second target level V2.

That is, the erase execution operation on the second cell string ST2 may be performed with a floating potential less than the floating potential during the erase execution operation on the first cell string ST1. Therefore, by the above-described erase execution method, an over-erasure phenomenon of the second cell string ST2 of which the erase speed is relatively fast compared to that of the first cell string ST1 may be prevented or mitigated.

When the erase execution operation is completed, the peripheral circuit 120 may perform a discharge operation on the first speed bit line BL1s connected to the first cell string ST1 and the source line SL from the fifth time point t55. In addition, the peripheral circuit 120 may perform the discharge operation on the second speed bit line BL2s connected to the second cell string ST2 from the fourth time point t54.

For example, when the erasure of the memory cells included in the first and second cell strings ST1 and ST2 is completed, the potential of the source line SL may be decreased to the discharge level Vds, and potentials of the first and second speed bit lines BL1s and BL2s may be decreased to the discharge level Vds.

The memory device 100 according to the fifth embodiment may perform the discharge operation on the second speed bit line BL2s connected to the second cell string ST2 having a relatively fast erase speed at an earlier time point than the discharge operation on the first speed bit line BL1s connected to the first cell string ST1 having a relatively slow erase speed.

That is, the peripheral circuit 120 performs the erase execution operation on the second cell string ST2 having a relatively fast erase speed for a shorter time than the erase execution operation on the first cell string ST1 having a relatively slow erase speed, so that the occurrence of an over-erasure phenomenon of the second cell string ST2 may be prevented or mitigated.

FIG. 6F is a diagram illustrating an erase operation of the memory device 100 according to a sixth embodiment of the present disclosure.

Referring to FIG. 6F, the peripheral circuit 120 of FIG. 1 may perform an erase setting operation on the first cell string ST1 from a first time point t61 to a third time point t63, and may perform the erase setting operation on the second cell string ST2 from a second time point t62 to the third time point t63.

The control logic 130 of FIG. 1 may apply an erase voltage to the source line SL and the first and second speed bit lines BL1s and BL2s to raise a potential of each of the source line SL and the first and second speed bit lines BL1s and BL2s.

Specifically, the potentials of the source line SL and the first speed bit line BL1s are at the discharge level Vds at the first time point t61, and may rise to the first target level V1 at the third time point t63. The potential of the second speed bit line BL2s is at the discharge level Vds during the period between the first time point t61 and the second time point t62, and may rise to the second target level V2 at the third time point t63.

That is, the peripheral circuit 120 may start the erase setting operation of the second cell string ST2 having a high erase speed at a time point later than the erase setting operation of the first cell string ST1. Thus, at the third time point t63 at which the erase setting operation of the first and second cell strings ST1 and ST2 is completed, the second speed bit line BL2s has the potential less than the potential of the first speed bit line BL1s.

The peripheral circuit 120 performs an erase execution operation on the first cell string ST1 from the third time point t63 to a fifth time point t65, and performs the erase execution operation on the second cell string ST2 from the third time point t63 to a fourth time point t64.

During the erase execution operation, the peripheral circuit 120 maintains a voltage of the source line SL at the first target level V1 and a voltage of the first speed bit line BL1s at the first target level V1. The peripheral circuit 120 maintains the voltage of the second speed bit line BL2s at the second target level V2 less than the first target level V1.

The peripheral circuit 120 performs the erase execution operation on the first cell string ST1 at the first target level V1 which is the potential of the first speed bit line BL1s, and performs the erase execution operation on the second cell string ST2 at the second target level V2 less than the first target level V1, which is the potential of the second speed bit line BL2s. That is, the peripheral circuit 120 erases the second cell string ST2 with a lower erase voltage than the first cell string ST1, so that the occurrence of an over-erasure phenomenon of the second cell string ST2 may be prevented or mitigated.

The peripheral circuit 120 may perform a discharge operation on the second speed bit line BL2s at the fourth time point t64 earlier than the fifth time point t65 which is a time point of the discharge operation on the first speed bit line BL1s. Therefore, a time required for the erase execution operation on the second cell string ST2 is shorter than that for the erase execution operation on the first cell string ST1.

The peripheral circuit 120 may discharge the potential of the first speed bit line BL1s to the discharge level Vds and discharge the potential of the second speed bit line BL2s to the third target level V3 greater than the discharge level Vds. That is, the peripheral circuit 120 may maintain the potential of the second speed bit line BL2s after the discharge operation greater than the potential of the first speed bit line BL1s after the discharge operation.

The peripheral circuit 120 performs the discharge operation of the second speed bit line BL2s at an earlier time point than the discharge operation of the first speed bit line BL1s. The voltage of the source line SL is also discharged at the time of discharging the first cell string ST1.

The memory device 100 according to the sixth embodiment may prevent or mitigate the occurrence of an over-erasure phenomenon of the second cell string ST2 by performing the erase execution operation of the second speed bit line BL2s connected to the second cell string ST2 having an erase speed faster than that of the first cell string ST1 for a shorter time than the erase execution operation of the first speed bit line BL1s connected to the first cell string ST1 during the erase operation of a memory block.

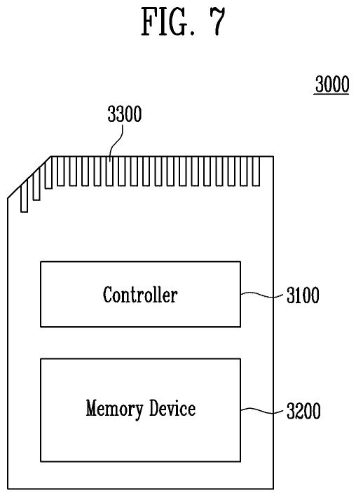

FIG. 7 is a diagram illustrating a memory card system 3000 to which a memory device 3200 according to an embodiment of the present disclosure is applied.

Referring to FIG. 7, the memory card system 3000 includes a controller 3100, the memory device 3200, and a connector 3300.

The controller 3100 is connected to the memory device 3200. The controller 3100 is configured to access the memory device 3200. For example, the controller 3100 may be configured to control a program, read, or erase operation of the memory device 3200, or to control a background operation. The controller 3100 is configured to provide an interface between the memory device 3200 and a host. The controller 3100 is configured to run firmware for controlling the memory device 3200. For example, the controller 3100 may include components such as a Random Access Memory (RAM), a processing unit, a host interface, a memory interface, and an error correction portion.

The controller 3100 may communicate with an external device through the connector 3300. The controller 3100 may communicate with the external device (e.g., a host) according to specific communication protocols. For example, the controller 3100 is configured to communicate with an external device via at least one of a variety of communication standards or interfaces, such as a Universal Serial Bus (USB), a multimedia card (MMC), an embedded MMC (eMMC), a peripheral component interconnect (PCI), a PCI-express (PCI-e or PCIe), Advanced Technology Attachment (ATA), Serial-ATA, Parallel-ATA, a small computer system interface (SCSI), an enhanced small disk interface (ESDI), Integrated Drive Electronics (IDE), Firewire, Universal Flash Storage (UFS), Wi-Fi, Bluetooth, or NonVolatile Memory express (NVMe). For example, the connector 3300 may be defined by at least one of the various communication standards or interfaces described above.

The memory device 3200 may include memory cells and may be configured the same as the memory device 100 shown in FIG. 1. For example, the memory device 3200 may include the erase information manager 131 of FIG. 1. Therefore, the memory device 3200 may be configured to perform at least one of the erase operations according to the first to sixth embodiments described above.

The controller 3100 and the memory device 3200 may be integrated into one semiconductor device to form a memory card. For example, the controller 3100 and the memory device 3200 may be integrated into one semiconductor device to form a memory card such as a Personal Computer Memory Card International Association (PCMCIA) memory card, a Compact Flash (CF) card, a smart media card (SM, SMC), a memory stick, a multimedia card (MMC, RS-MMC, MMCmicro, eMMC), Secure Digital (SD) card (SD, miniSD, microSD, SDHC), or a Universal Flash Storage (UFS) device.

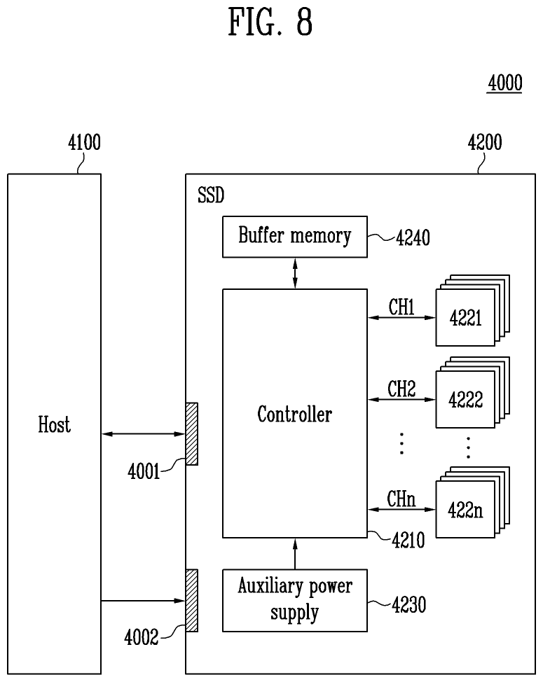

FIG. 8 is a diagram illustrating a Solid-State Drive (SSD) system 4000 to which a memory device according to an embodiment of the present disclosure is applied.

Referring to FIG. 8, the SSD system 4000 includes a host 4100 and an SSD 4200. The SSD 4200 exchanges a signal SIG with the host 4100 through a signal connector 4001, and receives power PWR through a power connector 4002. The SSD 4200 includes a controller 4210, a plurality of memory devices 4221 to 422n, an auxiliary power supply 4230, and buffer memory 4240.

The controller 4210 may control the plurality of memory devices 4221 to 422n in response to the signal received from the host 4100. For example, the signal may be based on an interface of the host 4100 and the SSD 4200. For example, the signal may be defined by at least one of communication standards or interfaces such as Universal Serial Bus (USB), multimedia card (MMC), embedded MMC (eMMC), peripheral component interconnect (PCI), PCI-express (PCI-e or PCIe), Advanced Technology Attachment (ATA), Serial-ATA, Parallel-ATA, small computer system interface (SCSI), enhanced small disk interface (ESDI), Integrated Drive Electronics (IDE), Firewire, Universal Flash Storage (UFS), Wi-Fi, Bluetooth, or NVMe interfaces.

The plurality of memory devices 4221 to 422n may include cells capable of storing data. Each of the plurality of memory devices 4221 to 422n may be configured in the same manner as the memory device 100 illustrated in FIG. 1. For example, each of the plurality of memory devices 4221 to 422n may include the erase information manager 131 of FIG. 1. Therefore, each of the plurality of memory devices 4221 to 422n may be configured to perform at least one of the erase operations according to the first to sixth embodiments described above.

The auxiliary power supply 4230 is connected to the host 4100 through the power connector 4002. The auxiliary power supply 4230 may receive a power voltage from the host 4100 and may be charged. The auxiliary power supply 4230 may provide the power voltage of the SSD 4200 when the power supply from the host 4100 is not smooth. For example, the auxiliary power supply 4230 may be located in the SSD 4200 or may be located outside the SSD 4200. For example, the auxiliary power supply 4230 may be located on a main board and may provide auxiliary power to the SSD 4200.

The buffer memory 4240 operates as buffer memory of the SSD 4200. For example, the buffer memory 4240 may temporarily store data received from the host 4100 or data received from the plurality of memory devices 4221 to 422n, or may temporarily store metadata (e.g., a mapping table) of the memory devices 4221 to 422n. The buffer memory 4240 may include volatile memory such as DRAM, SDRAM, DDR SDRAM, or LPDDR SDRAM, or non-volatile memory such as FRAM, ReRAM, STT-MRAM, or PRAM.

According to some embodiments of the present disclosure, the reliability of a memory device may be improved by preventing or mitigating the occurrence of an over-erasure phenomenon during an erase operation of the memory device. Furthermore, the embodiments may be combined to form additional embodiments.

What is claimed is:

1. A memory device comprising:
a memory block including a first cell string and a second cell string having a faster erase speed than the first cell string; and
a peripheral circuit configured to perform an erase operation on the memory block, the erase operation including an erase setting operation, an erase execution operation, and a discharge operation, which are sequentially performed,
wherein the peripheral circuit is configured to perform the erase execution operation of the first cell string for a first time period, and perform the erase execution operation of the second cell string for a second time period shorter than the first time period.

2. The memory device of claim 1, wherein the peripheral circuit is configured to perform the discharge operation on a second bit line connected to the second cell string before the discharge operation on a first bit line connected to the first cell string.

3. The memory device of claim 2, wherein the peripheral circuit is configured to maintain the first and second bit lines in a floating state in which each of the first and second bit lines has a potential less than a potential of a source line connected to the first and second cell strings during the erase execution operation of the memory block.

4. The memory device of claim 2, wherein the peripheral circuit maintains a potential of the second bit line after the discharge operation greater than a potential of the first bit line after the discharge operation during the discharge operation of the memory block.

5. The memory device of claim 4, wherein the potential of the first bit line is the same as the potential of the second bit line during the erase execution operation of the memory block.

6. The memory device of claim 2, wherein the peripheral circuit performs the erase setting operation of the second cell string at a later time point than the erase setting operation of the first cell string.

7. The memory device of claim 2, wherein the peripheral circuit floats the second bit line at a later time point than the first bit line during the erase setting operation.

8. The memory device of claim 7, wherein a floating potential of each of the first and second bit lines is less than a potential of a source line connected to the first and second cell strings during the erase execution operation.

9. The memory device of claim 7, wherein a floating potential of the second bit line is less than a floating potential of the first bit line.

10. A memory device comprising:
a memory block including a first cell string and a second cell string having a faster erase speed than the first cell string; and
a peripheral circuit configured to perform an erase operation on the memory block, the erase operation including an erase setting operation, an erase execution operation, and a discharge operation, which are sequentially performed,
wherein the peripheral circuit is configured to perform the erase setting operation of the second cell string at a later time point than the erase setting operation of the first cell string.

11. The memory device of claim 10, wherein a potential of a second bit line connected to the second cell string is less than a potential of a first bit line connected to the first cell string during the erase execution operation of the memory block.

12. The memory device of claim 10, wherein the peripheral circuit floats a second bit line connected to the second cell string at a later time point than a first bit line connected to the first cell string during the erase setting operation.

13. The memory device of claim 12, wherein a floating potential of the second bit line is less than a floating potential of the first bit line during the erase execution operation of the memory block.

14. A method of operating a memory device, the method comprising:
adjusting, to a target level, a voltage of a first bit line connected to a first cell string, a voltage of a second bit line connected to a second cell string, and a voltage of a source line connected to the first and second cell strings, the second cell string having a faster erase speed than the first cell string;
erasing data of the first and second cell strings; and
discharging each of the first bit line, the second bit line, and the source line,
wherein erasing the data includes erasing the data of the first cell string for a first time period and erasing the data of the second cell string for a second time period shorter than the first time period.

15. The method of claim 14, wherein discharging each of the first bit line, the second bit line, and the source line includes discharging the second bit line before the first bit line is discharged.

16. The method of claim 15, wherein discharging each of the first bit line, the second bit line, and the source line includes discharging a potential of the second bit line which is greater than a potential of the first bit line which is discharged.

17. The method of claim 16, wherein during the erasing of the data, the potential of the first bit line is the same as the potential of the second bit line.

18. The method of claim 15, wherein adjusting the voltages to the target level comprises:
increasing the voltage of the first bit line to the target level; and
increasing the voltage of the second bit line to the target level.

19. The method of claim 15, wherein adjusting the voltages to the target level includes floating the second bit line at a later time point than the first bit line.

20. The method of claim 19, wherein during the erasing of the data, a floating potential of the second bit line is less than a floating potential of the first bit line.
